(19) United States
(12) Patent Application Publication
(10) Pub. No.: US 2010/0200897 A1
(43) Pub. Date: Aug. 12, 2010

(54) TRANSISTOR AND METHOD OF MANUFACTURING THE SAME

(75) Inventors: Anco Heringa, Waalre (NL); Philippe Meunier-Beillard, Kortenberg (BE); Raymond Duffy, Leuven (BE)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/676,007

(22) PCT Filed: Aug. 27, 2008
(86) PCT No.: PCT/IB08/53448

§ 371 Date: Mar. 2, 2010

(30) Foreign Application Priority Data
Sep. 5, 2007 (EP) 07115716.8

(51) Int. Cl. H01L 29/78; H01L 21/336

(52) U.S. Cl. 257/288; 438/305; 257/E21.409; 257/E29.255

(57) ABSTRACT

A method of manufacturing a transistor (400), the method comprising forming a gate (101) on a substrate (102), forming a spacer (201) on lateral side walls of the gate (101) and on an adjacent portion (202) of the substrate (102), rearranging material of the spacer (201) so that the rearranged spacer (301) covers only a lower portion (303) of the lateral side walls of the gate (101) and an increased portion (302) of the substrate (102), and providing source/drain regions (402, 403) in a portion of the substrate (102) below the rearranged spacer (301).

### FIELD OF THE INVENTION

The invention relates to a transistor.

Moreover, the invention relates to a method of manufacturing a transistor.

### BACKGROUND OF THE INVENTION

The aggressive gate length downscaling in CMOS technology for logical applications may allow that a CMOS transistor could now reach a frequency domain which was previously reserved for bipolar transistors.

A MOSFET device may be considered to be short when the channel length is in the same order of magnitude as the depletion layer width of the source and drain junction. As the channel length may be reduced to increase both the operation speed and the number of components per chips, so-called short channel effects may arise which implied that the transistors are becoming more and more leaky.

When the depletion region surrounding the drain extends to the source (so that the two depletion layers merge), leakage or punch-through may occur which can be reduced or minimized in different ways like with the use of thinner gate oxide layers, larger substrate doping, shallower junctions, and with a longer channel. The use of raised source/drain is also an efficient way to improve with respect to the short channel effects, because it allows more shallow source/drains. It is also possible to reduce the series resistance of source/drain regions with elevated source/drains. This technique usually requires selective epitaxy growth which is difficult to implement in a production environment.

For the scaling, that is reduction in size, of devices in integrated circuits, all dimensions have to be reduced. As a consequence the junction depth has to be reduced. This reduction of depth should not reduce the conductivity of the source/drain regions from the channel edge to the source/drain contacts. Increasing the doping level of the source/drain areas enhances the conductivity but also enhances the electric field at these junctions including higher leakage and lower breakdown voltages of these junctions. Both latter effects are detrimental for further scaling. Therefore, it is desirable to have a device in which the dimensions are reduced, and simultaneously the doping levels are increased, but on the other hand it is desired to limit the resulting field increase as much as possible.

Curvature of junctions includes high electric fields at these curved junctions: The lower the radius the higher the field. With decreasing dimensions, the radius goes down so the field goes up. If one could avoid or reduce the junction curvature (this lower curvature results in a larger effective radius), the electric field would go up less with the ever increasing doping levels.

Shaping a gradually increasing source/drain extension depth by using a number of implants with varying implant tilts or growing elevated source/drains may remedy the excessive increase of the electric field due to the scaling, but may be expensive. Such a multiple implant method is not only expensive, but may also implant part of the extension through the gate oxide. This may harm the gate oxide integrity. The elevated source/drain by epitaxial growth is not only expensive but also induces extra source/gate, drain/gate and source/drain capacitances which may be problematic for high frequency operation.

U.S. Pat. No. 5,953,615 discloses MOSFETs with deep source/drain junctions and shallow source/drain extensions, and provides on a semiconductor wafer a gate stack with side spacers. The side spacers are etched so that a known thickness of the side spacers is left. An ion beam is used to implant Si+ or Ge+ or Xe+ to amorphize the silicon region, creating an amorphous region with two different depths. A high dose ion beam is then used to implant a dopant. An oxide layer is then deposited as a barrier layer, and then a metal layer is deposited to improve laser energy absorption. Laser annealing is used to melt the amorphous silicon region which causes the dopant to diffuse in and into the amorphous silicon region creating deep source/drain junctions and shallow source/drain extensions. Standard techniques are then used to complete the transistor, which includes silicidation of the source/drain junctions.

However, such transistor manufacture procedures may be cumbersome and expensive.

### OBJECT AND SUMMARY OF THE INVENTION

It is an object of the invention to provide a scalable transistor architecture manufacturable with reasonable effort.

In order to achieve the object defined above, a transistor, and a method of manufacturing a transistor according to the independent claims are provided.

According to an exemplary embodiment of the invention, a method of manufacturing a transistor is provided, the method comprising forming a gate on a substrate, forming a spacer on lateral side walls of the gate (that is walls of the gate being perpendicular to a main surface of the substrate) and on an adjacent portion of the substrate (more precisely on a surface portion of the substrate which surface portion is directly neighboured to the gate), rearranging material of the spacer (that is modifying a spatial distribution of material of the spacer) so that the rearranged spacer covers only a lower portion of the lateral side walls of the gate (that is a portion of the lateral side wall which is closer or adjacent to the substrate) and an increased portion of the substrate (more precisely an increased portion of an exposed surface of the substrate), and providing source/drain regions in a portion of the substrate below (or under) the rearranged spacer.

According to another exemplary embodiment of the invention, a transistor is provided, the transistor comprising a substrate, a gate on the substrate, a concave spacer (for instance rearranged in accordance with the above described method) which covers only a lower portion of lateral side walls of the gate and a portion of the substrate, and source/drain regions in a portion of the substrate below the concave spacer.

The term “substrate” may denote any suitable material, such as a semiconductor, glass, plastic, etc. According to an exemplary embodiment, the term “substrate” may be used to define generally the elements for layers that underlie and/or overlie a layer or portions of interest. Also, the substrate may be any other base on which a layer is formed, for example a semiconductor wafer such as a silicon wafer or silicon chip.

The transistor may be a field effect transistor. The term “field effect transistor” (FET) may denote a transistor in which an output current (source-drain current) may be controlled by the voltage applied to a gate which can be an MOS structure (MOSFET), a p-n junction (JFET), or metal-semiconductor contact (MESFET). A FET is a unipolar transistor, that is current is controlled by majority carriers only.

The term “source/drain region” may particularly denote a source region or a drain region. Since the functionality of a source region and a drain region may depend on the operation mode of a (memory or logic) transistor, for instance voltages applied thereto, the term source/drain region may denote a structure which can act as a source region or as a drain region.

The term “gate” may denote an electrically conductive structure to which an electric voltage may be applied to control a conductivity of a channel region of a semiconductor substrate. In the context of this application, the term gate may cover such an electrically conductive structure individually, or the electrically conductive structure with at least one electrically insulating component connected thereto. Thus, also a gate stack may be covered by the term “gate”.

The term “rearranging” may particularly denote any treatment by which spacer material is migrated, moved or transferred along the lateral walls of the gate stack. Such a rearrangement may be performed essentially without adding material to the spacer and essentially without removing material from the spacer.

The term “concave” may particularly denote curved downwards, when seen from the top of the layer sequence.

The term “convex” may particularly denote curved upwards, when seen from the top of a layer sequence.

According to an exemplary embodiment of the invention, a spacer is provided on a side wall of a gate stack for the purpose to obtain a slanted source/drain region by first forming a spacer conventionally on a lateral sidewall of a gate stack, and by subsequently migrating material of this spacer to thereby move part of the material to a lower portion of the substrate, thereby forcing it to cover a larger area on the substrate and a smaller area on the lateral walls of the gate stack. By taking this measure, such a rearranged spacer may serve as an implantation absorber having a varying thickness allowing to implant dopants in the surface of the substrate adjacent the rearranged spacer in a manner that the depth of the source/drain increases from a portion next to the gate stack to a portion remote from the gate stack.

By taking this measure, the increase of the electric field may be avoided to a large extent by suppressing the enhancement of the electric field at the edge of the source/drain regions. This may be obtained by shaping source/drain with gradually increasing depths, in a lateral direction. In other words, a method for making source/drain extensions may be provided with a depth which gradual increases when going from channel towards the contact area of the source/drain regions.

Therefore, implanting the source/drain extension through an absorbing/scattering layer which is thicker at the gate stack edge than farther from the gate edge may result in source/substrate and drain/substrate junctions which are shallow at the gate edge and deeper farther from this gate edge. This may enable to further reduce the gate length of a transistor without a detrimental short channel effect as with source/substrate and drain/substrate junctions. An increase of the series resistance may be kept relatively small because of the gradual thickening of the extension (with a thinner layer on top through which is implanted). Further, a reduction of the breakdown voltage and an increase of the leakage may be minor because there will be no field peaks when ensuring a sufficiently large curvature radius.

A process to create such a gradually increasing junction depth according to an exemplary embodiment of the invention can be as follows:

perform conventional MOS processing until after gate patterning

create an implant absorbing/scattering layer which is thicker at the gate edge than farther from the gate edge

implant the source/drain extension

remove the absorbing/scattering layer and continue with standard processing or, if possible or desired, keep this layer for further processing. Thus, after source/drain implantation, it is possible to keep or remove the absorbing layer.

Thus, the source/drain extension may be implanted through an absorbing/scattering layer that is relatively thicker at the gate edge than farther from the gate edge. This may allow to suppress an enhancement of the electric field at the edge of the source/drain regions, and may allow to obtain low source/drain resistance with shallow junctions at the channel edge allowing better length scaling without sacrificing much on junction leakage and breakdown voltage.

Next, further exemplary embodiments of the method will be explained. However, these embodiments also apply to the transistors.

The method may comprise implanting the source/drain regions in a portion of the substrate below the rearranged spacer. In one embodiment, the rearranged spacer may serve as an absorption layer which controls an amount of dopant to be introduced into the substrate by providing a spatially dependent absorption characteristic to form source/drain regions in the substrate having a small thickness close to the gate and a larger thickness remote thereof.

The method may further comprise rearranging the material of the spacer by annealing, particularly by hydrogen annealing (that is annealing in hydrogen atmosphere). Such a procedure may be performed at a temperature in a range of, for example, 600° C. to 1000° C., at a pressure in a range of, for example, 1 Torr to 100 Torr, and for a time in a range of, for instance, 10 seconds to 10 minutes. This may allow to force the material of the spacer to migrate or to sink towards the surface of the substrate, thereby allowing to control an extent to which an upper portion of the lateral sidewall of the gate stack is free of the spacer after the rearranging procedure. Therefore, it may be achieved that not the entire sidewall of the gate stack remains covered with the material of the rearranged spacer, so that the thickness variation of the source/drain region is not too extreme, yielding a smooth transition of the depth of the source/drain regions. By adjusting the parameters of the rearrangement procedure, for instance the time interval during which the layer sequence is made subject to the annealing procedure, an amount of rearranging/migrating may be controlled with high precision.

The method may comprise rearranging the material of the spacer with a thickness which gradually increases towards the gate. Therefore, an essentially stepless doping profile may be obtained in the source/drain regions, and therefore the thickness of the source/drain region continuously passes over from a very thick portion away from the gate stack to a very thin portion close to the gate stack.

The method may comprise removing the rearranged material of the spacer after providing/forming the source/drain regions in the substrate covered by the rearranged material. Such an embodiment may be particularly advantageous when the spacer is only used as an absorption or dopant thickness control layer, which can be removed after having implanted the source/drain regions within the substrate.

The method may comprise forming a protection structure, particularly an essentially L-shaped protection structure (see reference numeral 901), between the gate and the spacer. The term “L-shaped” may denote a shape of the protection structure in a cross-sectional view of the layer sequence which may result in an appearance of the protection structure to have the shape of two letters “L” at the two lateral sidewalls of the gate stack visible in such a cross-sectional view. Such a protection structure may protect the gate stack against possibly chemically aggressive material of the spacer, thereby ensuring a high quality of the manufactured transistor.

The method may comprise forming the spacer on the lateral sidewalls of the gate and on the adjacent portion of the substrate by (for instance conformally) depositing spacer material over the gate and the substrate, and subsequently removing (for instance by etching) part of the spacer material so that the spacer remains only on lateral sidewalls of the gate and on the adjacent portions of the substrate. Thus, a conformal deposition of the spacer material, for instance SiGe, may be followed by an etching procedure which forms essentially convex spacers at the lateral sidewalls of the gate stack. Subsequently, the rearrangement may convert this convex structure into a concave structure, for example by annealing.

In the following, further exemplary embodiments of the transistor will be explained. However, these embodiments also apply to the method.

The spacer may have a concave shape. Thus, after the rearrangement, the shape of the spacer may be concave in a similar manner as an avalanche which has slipped down or glided down a hill. The extent to which the material has been rearranged then also has an impact on the curvature of the concave spacer.

The spacer may comprise a material of the group consisting of silicon-germanium (SiGe), a polymer, silicon, silicon oxide (SiO₂), and silicon nitride (Si₃N₄). Silicon-germanium may be a preferred choice since this may be rearranged efficiently by hydrogen annealing. A polymer spacer has the advantage that it can be easily removed after usage as an absorber.

The source/drain regions in the portion of the substrate below the spacer may have a gradually decreasing depth towards the gate. Thus, the shape of the source/drain regions may simply be a negative or inverse of the shape of the rearranged spacer.

The transistor may comprise a further spacer on a lateral wall of the gate, essentially (that is at least to a main part) above the spacer, and having a thickness smaller than the thickness of the spacer. This additional spacer may prevent silicidation bridging between the source/drain regions and a polysilicon gate.

The further spacer may be a convex spacer. Thus, the transistor may comprise a concave spacer used for defining a design of the source/drain regions in the substrate, and may comprise a further concave spacer for protection purposes. The further spacer may have a height which is higher than the height of the spacer, but may have a width which is smaller than the width of the spacer.

Embodiments of the invention are applicable to crystalline silicon wafers. Other embodiments are applicable on SOI (Silicon On Insulator) wafers. However, the silicon migration may also occur on the top silicon or on top of the box oxide. A hydrogen anneal of 800° C. may be applied to SOI wafers with silicon layers as thin as 8 nm. Lower hydrogen anneal temperatures may be used by increasing the Ge concentration and decreasing the oxide thickness under the SiGe layer. The SiGe spacer may be replaced by a dummy gate.

Exemplary embodiments of the invention may be applied to any CMOS application allowing low source/drain resistance with shallow junctions at the channel edge allowing proper length scaling and also in CMOS applications requiring higher operating voltages such as in RF power CMOS.

According to an exemplary embodiment, it may be possible to create a slanted shape of the source/drain extension, so that shape controlling may be performed particularly with a hydrogen annealing. This is an elegant way of making a slanted source/drain extension boundary.

According to an exemplary embodiment of the invention, after rearranging, a vertical thickness of the rearranged spacer is smaller than a vertical thickness of the gate stack. This avoids to have a slanted extension having a depth which varies from quite shallow at the gate edge to a depth closer or equal to the gate thickness farther from the gate. Since after rearranging, only a portion of the lateral sidewall of the gate stack is covered with the rearranged material of the spacer, it is possible to have a low resistance and shallow source/drain extensions at the gate edge. This allows tuning of the absorption thickness at the gate edge and tuning of its width. Therefore, a shallow and low resistance source/drain extension may be obtained.

The device may be manufactured in CMOS technology. Any CMOS technology generation may be used. When using CMOS technology, a known and cheap method may be used for manufacturing the transistor.

The substrate may be a semiconductor substrate. The transistor device may be monolithically integrated in the semiconductor substrate, particularly comprising one of the group consisting of a group IV semiconductor (such as silicon or germanium), and a group III-group V semiconductor (such as gallium arsenide).

For any method step, any conventional procedure as known from semiconductor technology may be implemented. Forming layers or components may include deposition techniques like CVD (chemical vapour deposition), PECVD (plasma enhanced chemical vapour deposition), ALD (atomic layer deposition), or sputtering. Removing layers or components may include etching techniques like wet etching, plasma etching, etc., as well as patterning techniques like optical lithography, UV lithography, electron beam lithography, etc.

Embodiments of the invention are not bound to specific materials, so that many different materials may be used. For conductive structures, it may be possible to use metallization structures, silicide structures or polysilicon structures. For semiconductor regions or components, crystalline silicon may be used. For insulating portions, silicon oxide or silicon nitride may be used.

The transistor may be formed on a purely crystalline silicon wafer or on an SOI wafer (Silicon On Insulator).

Any process technologies like CMOS, BIPOLAR, BICMOS may be implemented.

The aspects defined above and further aspects of the invention are apparent from the examples of embodiment to be described hereinafter and are explained with reference to these examples of embodiment.

### BRIEF DESCRIPTION OF THE DRAWINGS

The invention will be described in more detail hereinafter with reference to examples of embodiment but to which the invention is not limited.

FIG. 1 to FIG. 4 show layer sequences obtained during a method of manufacturing a transistor according to an exemplary embodiment of the invention.

FIG. 5 to FIG. 22 show layer sequences obtained during another method of manufacturing a transistor according to an exemplary embodiment of the invention.

### DESCRIPTION OF EMBODIMENTS

The illustration in the drawing is schematical. In different drawings, similar or identical elements are provided with the same reference signs.

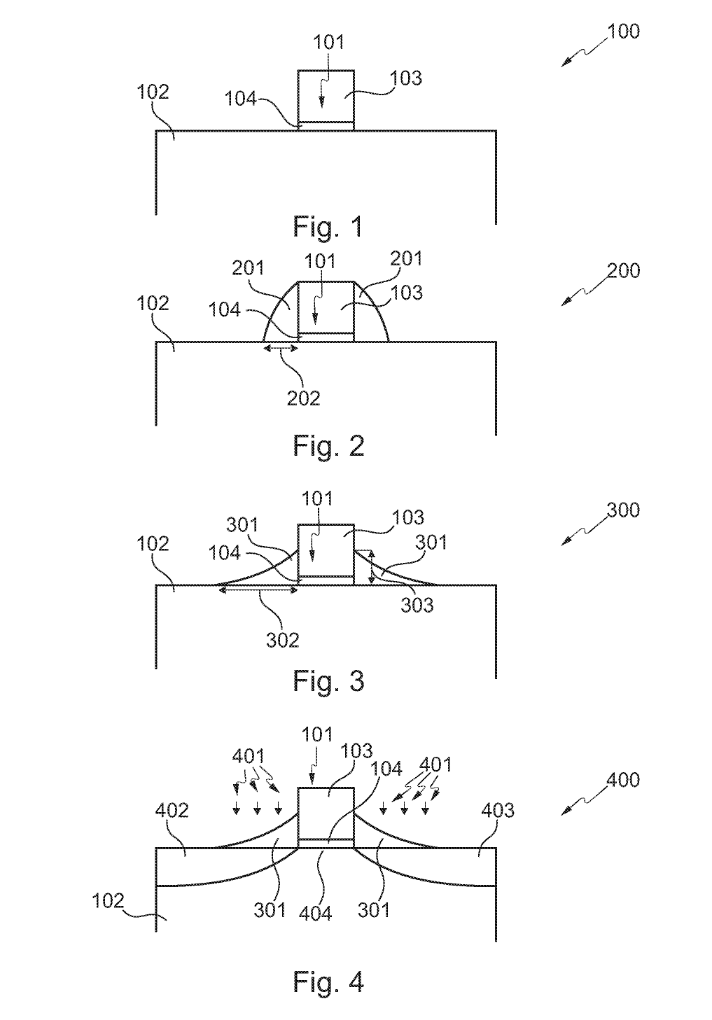

In the following, referring to FIG. 1 to FIG. 4, a method of manufacturing a transistor 400 according to an exemplary embodiment of the invention will be explained.

As can be taken from a layer sequence 100 shown in FIG. 1, a gate stack 101 is formed on a silicon substrate 102. The gate stack 101 comprises a poly silicon gate 103 and a gate oxide layer 104. The gate oxide layer 104 may be deposited as a silicon oxide layer on the silicon substrate 102 or may be formed by thermally oxidizing the silicon material at the surface of the silicon substrate 102. A poly silicon layer may be deposited on top of the gate oxide layer 104 and may be patterned using a lithography to obtain the laterally confined gate 103.

In order to obtain a layer sequence 200 shown in FIG. 2, a spacer 201 is formed on entire lateral sidewalls of the gate stack 101 and on an adjacent portion 202 of the substrate 102.

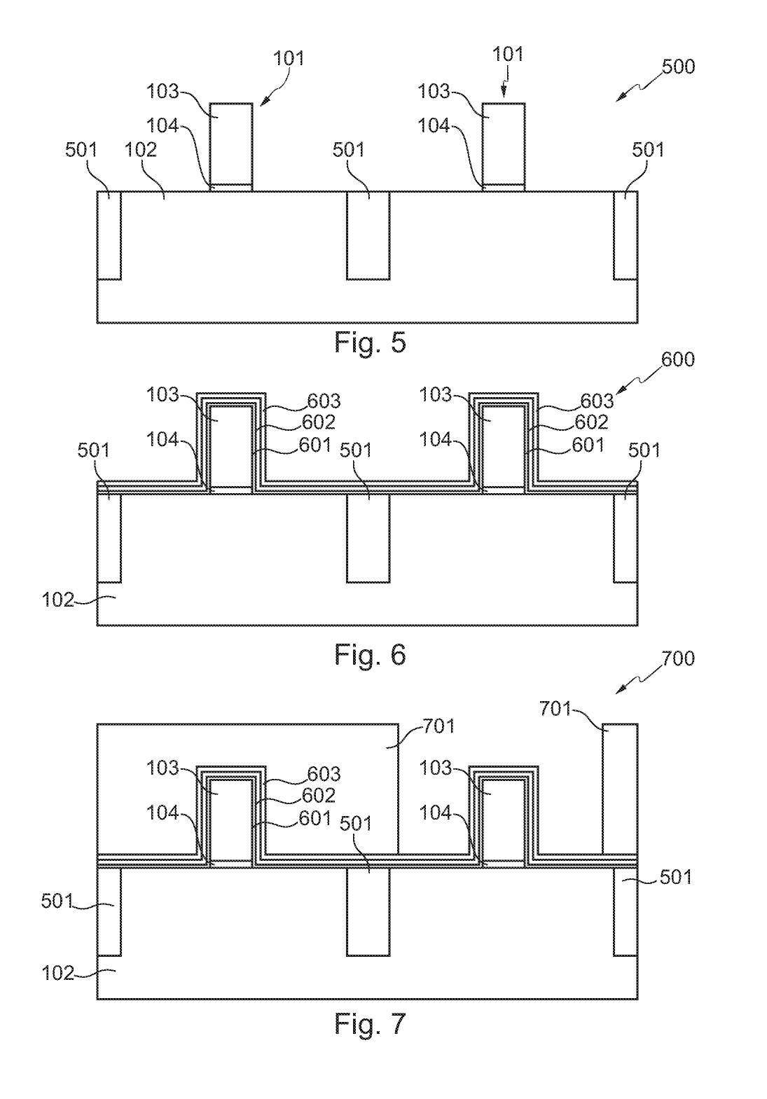

The spacer 201 may be made of silicon-germanium material (as will be described in more detail referring to the embodiment shown in FIG. 5 to FIG. 22).

In order to obtain a layer sequence 300 shown in FIG. 3, material of the spacer 201 is rearranged by thermally annealing the layer sequence 200 in hydrogen atmosphere, so that the rearranged spacer 301 covers only a lower sub-portion 303 of the lateral sidewalls of the gate stack 101 and an increased portion 302 of the substrate 102, as compared to the layer sequence 200. Furthermore, a convex geometry of the spacer 201 is converted into a concave geometry of the rearranged spacer 301.

A transistor 400 shown in FIG. 4 can be manufactured by using the rearranged spacers 301 as an absorption layer which absorbs a part of implantation atoms 401 implanted into a surface portion of the substrate 102. Namely, since the thickness of the rearranged spacer 301 is larger close to the gate stack 101 than farther away therefrom, a larger portion of the implantation 401 is absorbed close to the gate stack 101 than far away therefrom. Therefore, a thickness or depth of a first source/drain region 402 and of a second source/drain region 403 is small close to a channel region 404, and is relatively large far away therefrom. Therefore, source/drain profiles 402, 403 can be manufactured which are slanted and which gradually decrease when approaching the layer stack 101.

In the following, referring to FIG. 5 to FIG. 22, a method of manufacturing a transistor according to an exemplary embodiment of the invention will be explained. The thicknesses of layers mentioned in the following are specified only for giving an exemplary order of magnitude, and exact thicknesses can vary from the given thicknesses. Thus, thickness values are only exemplary and may vary over broad ranges.

In order to obtain a layer sequence 500 shown in FIG. 5, STI (shallow trench isolation) structures 501 are formed in a silicon substrate 102. Gate stacks 101 are formed comprising a gate insulation layer 104 and a poly silicon gate 103.

In order to obtain a layer sequence 600 shown in FIG. 6, a silicon oxide layer 601, for instance having a thickness of 3 nm, a silicon nitride layer 602 having a thickness of 5 nm, and an amorphous silicon layer 603 having a thickness of 5 nm are deposited on the layer sequence 500.

In order to obtain a layer sequence 700 shown in FIG. 7, a photoresist layer 701 is spun over the layer sequence 600, and a lithography is performed in order to expose the portion of the layer sequence 600 on which a transistor according to an exemplary embodiment of the invention shall be formed.

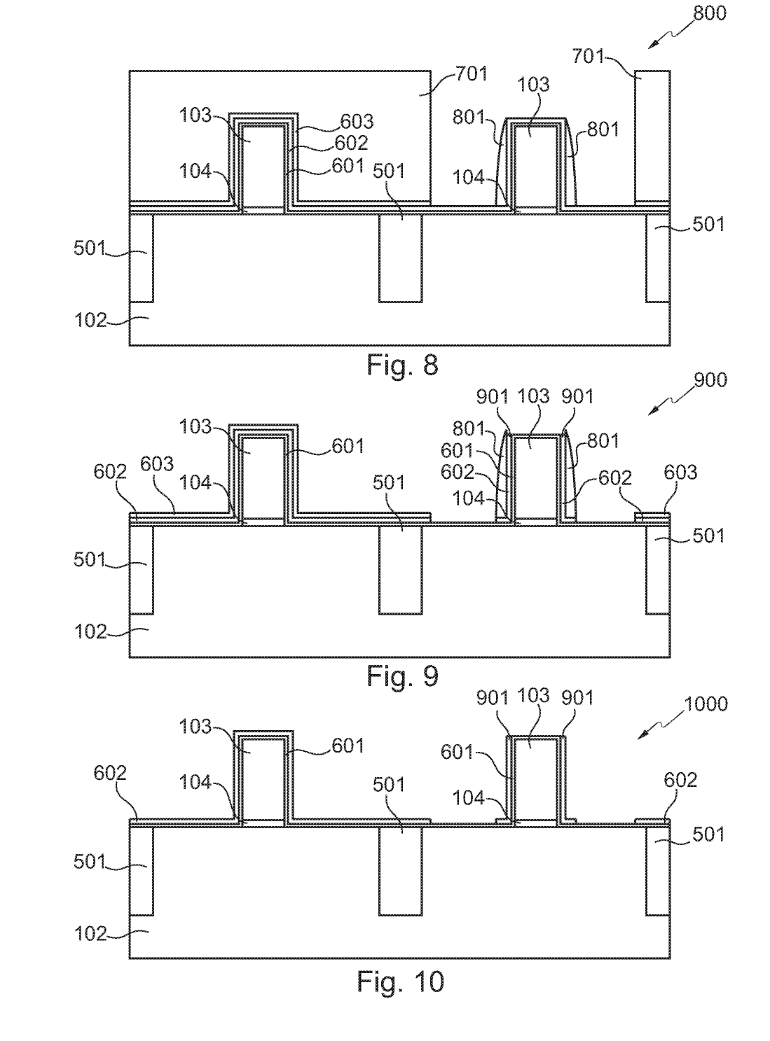

In order to obtain a layer sequence 800 shown in FIG. 8, an a-Si spacer formation is performed by removing an exposed portion of the silicon layer 603 resulting in the formation of silicon spacers 801.

In order to obtain a layer sequence 900 shown in FIG. 9, the resist 701 is stripped and a silicon nitride etch is performed. This removes exposed surface portions of the silicon nitride layer 602. As can be taken from FIG. 9, the remaining portions of the silicon nitride layer 602 on the gate stack on the right-hand side of FIG. 9 form essentially L-shaped spacers 901.

In order to obtain a layer sequence 1000 shown in FIG. 10, an a-Si etch is performed thereby removing remaining portions of the silicon material 603, 801 exposed in FIG. 9.

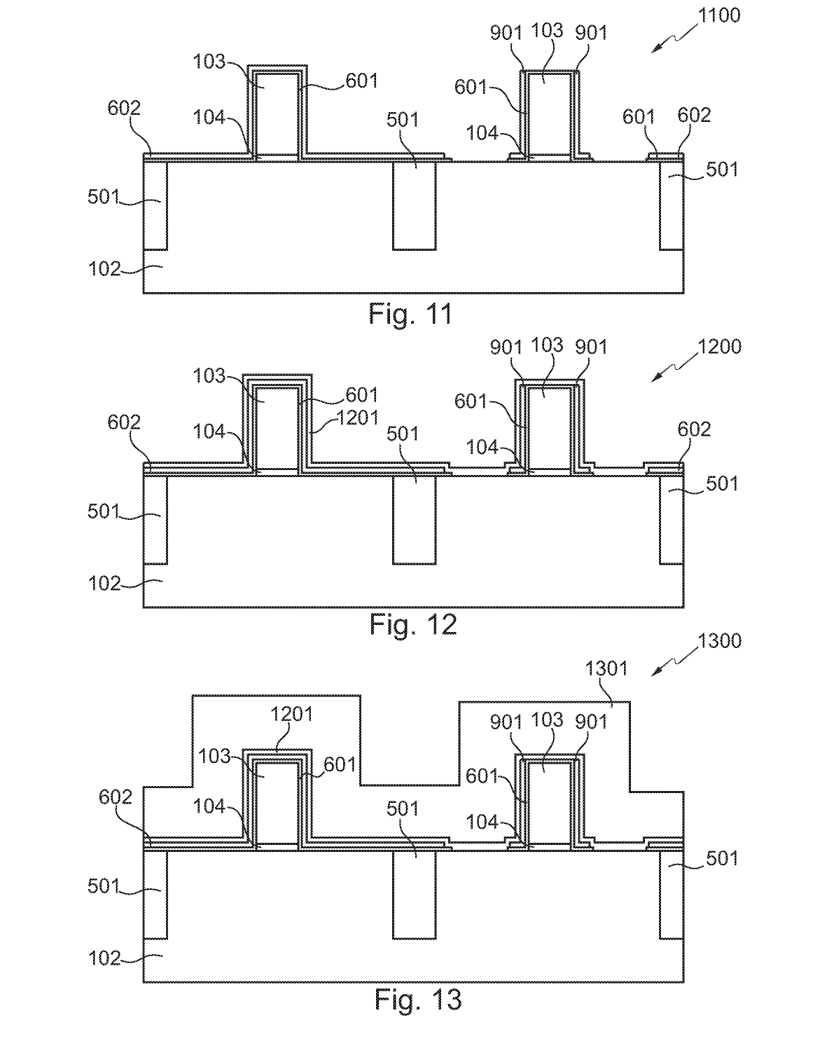

In order to obtain a layer sequence 1100 shown in FIG. 11, a silicon oxide etch is performed to remove exposed portions of the layer 601.

In order to obtain a layer sequence 1200 shown in FIG. 12, a silicon oxide layer 1201 having a thickness of for instance 5 nm is deposited over the layer sequence 1100.

In order to obtain a layer sequence 1300 shown in FIG. 13, a-SiGe is deposited over the layer sequence 1200, thereby forming a conformal SiGe layer 1301.

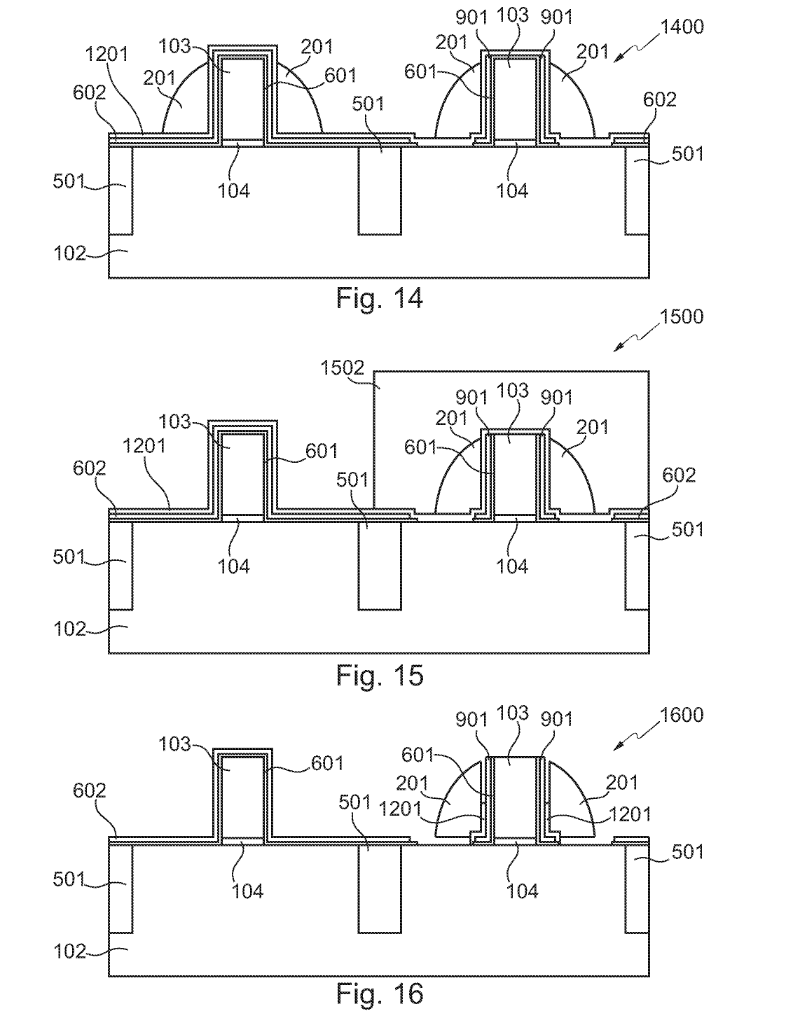

In order to obtain a layer sequence 1400 shown in FIG. 14, the SiGe layer 1301 is etched to form a-SiGe spacers 201.

In order to obtain a layer sequence 1500 shown in FIG. 15, a photoresist 1502 is spun, and a lithography is performed to maintain only a portion of the layer sequence 1400 covered with photoresist 1502 on which portion the transistor according to an exemplary embodiment of the invention shall be formed. Subsequently, an a-SiGe etch is performed in order to remove the spacer 201 on the gate stack on the left-hand side of FIG. 15.

In order to obtain a layer sequence 1600 shown in FIG. 16, the resist 1502 is stripped, and a silicon oxide etch is performed to remove exposed portions of layer 1201.

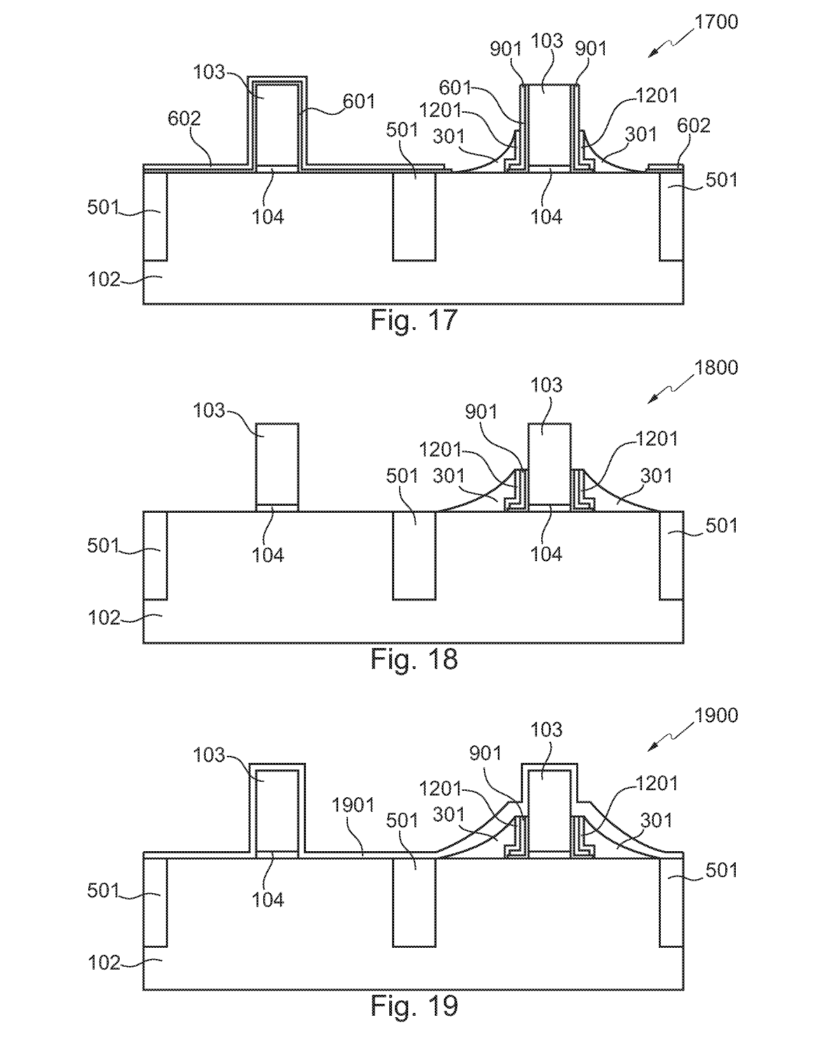

In order to obtain a layer sequence 1700 shown in FIG. 17, the layer sequence 1600 is made subject to a hydrogen anneal procedure to thereby rearrange the material of the convex spacer 201 to form a rearranged concave spacer 301.

In order to obtain a layer sequence 1800 shown in FIG. 18, a silicon nitride etch and a silicon oxide etch may be performed to remove layers 602, 601 and portions of the remaining structures 901, 1201.

In order to obtain a layer sequence 1900 shown in FIG. 19, a silicon oxide deposition is performed to form a conformally deposited silicon oxide layer 1901.

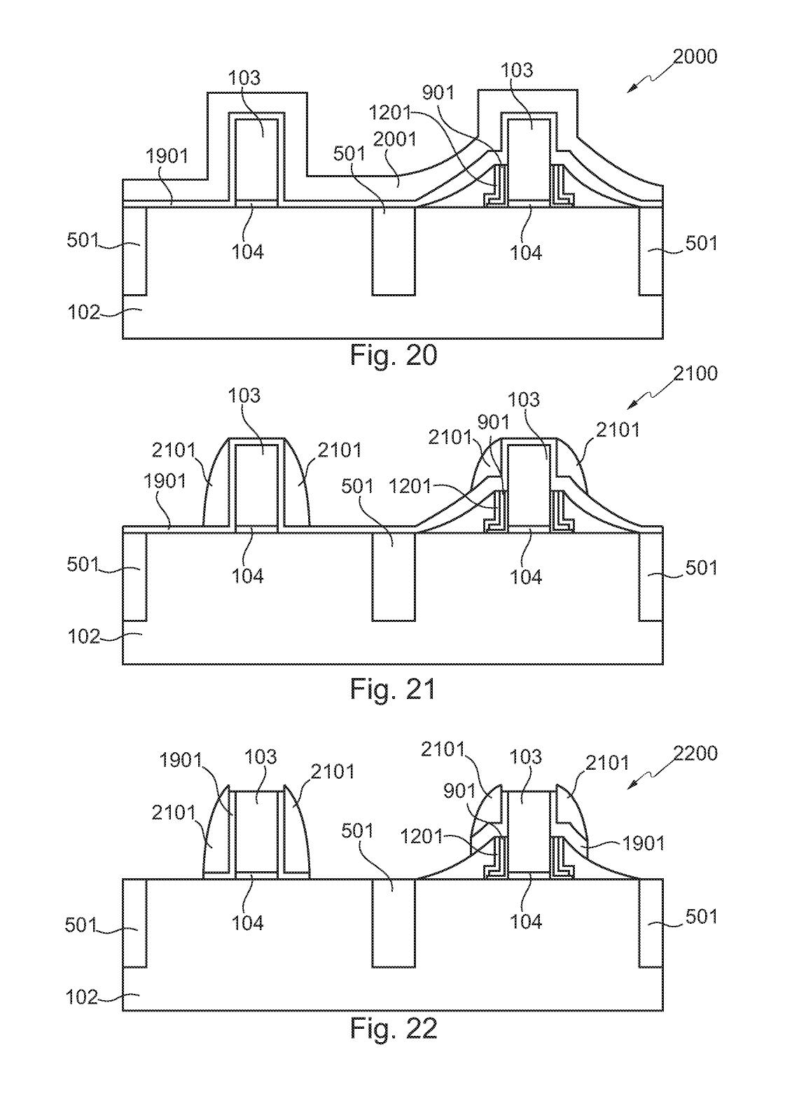

In order to obtain a layer sequence 2000 shown in FIG. 20, a silicon nitride deposition is performed in order to produce a silicon nitride layer 2001.

In order to obtain a layer sequence 2100 shown in FIG. 21, a silicon nitride etch is performed to produce the silicon nitride spacers 2101.

After having performed a silicon oxide etch, a layer sequence 2200 as shown in FIG. 22 is obtained including, on the right-hand side, a transistor according to an exemplary embodiment of the invention.

Regarding to the process integration scheme described referring to FIG. 5 to FIG. 22, important aspects of the described embodiment of the invention are implemented between the gate patterning of FIG. 5 and the further spacer formation of FIG. 19.

The process integration starts with the deposition of silicon oxide 601, silicon nitride 602 and amorphous silicon layer 603, as shown in FIG. 6. The silicon nitride layer 602 is used as a protective layer for mainstream CMOS, and the silicon nitride layer 602 is also used for the formation of the L-shaped spacer 901 for the dedicated transistors with an elevated source/drain. A mask 701 is used (see FIG. 7) in order to create a silicon spacer 801 (see FIG. 8). The resist 701 is stripped and silicon nitride 602 is etched (see FIG. 9). Only the silicon nitride 602 on the poly gate 103 and on the source/drain area is removed. The a-Si 603 is removed selectively to silicon nitride 602 and silicon oxide 601 (see FIG. 10). The remaining protective silicon oxide 601 on the source/drain and poly gate is removed (see FIG. 11), and a further silicon oxide layer 1201 (with accurate thickness) is deposited (see FIG. 12). The thickness of this silicon oxide layer 1201 may be rather important because it may determine the silicon oxide etch rate undercut in FIG. 16 and the sealing of the layer in FIG. 17. An amorphous SiGe layer 1301 is deposited (see FIG. 13), and SiGe spacers 201 are formed (see FIG. 14).

It may be advantageous (but not mandatory) to apply a short SiGe anisotropic etch (like APM, ammonia and hydrogen peroxide mixtures) in order to “recess” the SiGe spacers 201 such that the spacer height is lower than the poly gate 103. Unwanted SiGe spacers 201 may be etched away using a mask (see FIG. 15). An HF dip may be used in order to remove the silicon oxide layer 1201 underneath the SiGe spacer 201 (see FIG. 16). The SiGe spacers 201 are spread out using a hydrogen anneal (see FIG. 17). A typical hydrogen anneal is performed at 800° C., 10 Torr and one minute for a SiGe layer with a Germanium concentration around 30 at. %. The silicon-germanium layer 301 will recrystallize or have epitaxial realignment such that the interface is defect free. The silicon nitride spacer 2101 prevents the merging and/or the deformation of the poly gate 103. The protective silicon nitride layer 602 and silicon oxide layer 601 are removed (see FIG. 18), and CMOS processing is continued. The CMOS spacer formation is illustrated between FIG. 19 and FIG. 22.

The source/drain dopant engineering (not shown in FIG. 5 to FIG. 22) may be performed in different ways. Particularly, the rearranged spacers 301 may be used as absorption structures having a spatially slightly dependent thickness. In the presence of these spacers 301, the layer sequence may be made subject of an implantation procedure, similarly as shown in FIG. 4, for generating source-/drain regions.

Finally, it should be noted that the above-mentioned embodiments illustrate rather than limit the invention, and that those skilled in the art will be capable of designing many alternative embodiments without departing from the scope of the invention as defined by the appended claims. In the claims, any reference signs placed in parentheses shall not be construed as limiting the claims. The words “comprising” and “comprises”, and the like, do not exclude the presence of elements or steps other than those listed in any claim or the specification as a whole. The singular reference of an element does not exclude the plural reference of such elements and vice-versa. In a device claim enumerating several means, several of these means may be embodied by one and the same item of software or hardware. The mere fact that certain measures are recited in mutually different dependent claims does not indicate that a combination of these measures cannot be used to advantage.

1. A method of manufacturing a transistor, the method comprising:
forming a gate on a substrate;
forming a spacer on lateral side walls of the gate and on an adjacent portion of the substrate;
rearranging material of the spacer such that the rearranged spacer covers only a lower portion of the lateral side walls of the gate and an increased portion of the substrate;
providing source/drain regions in a portion of the substrate below the rearranged spacer.

2. The method of claim 1, comprising implanting the source/drain regions in the portion of the substrate below the rearranged spacer.

3. The method of claim 1, comprising rearranging the material of the spacer by annealing.

4. The method of claim 1, comprising rearranging the material of the spacer in such a manner that a thickness of the rearranged spacer gradually increases towards the gate.

5. The method of claim 1, comprising removing the rearranged spacer after providing the source/drain regions in the portion of the substrate below the rearranged spacer.

6. The method of claim 1, comprising forming a protection structure, particularly a protection structure being essentially L-shaped in a cross-sectional view, between the gate the spacer.

7. The method of claim 1, comprising forming the spacer on the lateral side walls of the gate and on the adjacent portion of the substrate by
depositing spacer material over the gate and the substrate; and
removing part of the spacer material so that the spacer remains only on the lateral side walls of the gate and on the adjacent portion of the substrate.

8. A transistor, the transistor comprising
a substrate;
a gate on the substrate;
a concave spacer which covers only a lower portion of lateral side walls of the gate and a portion of the substrate;
source/drain regions in a portion of the substrate below the concave spacer.

9. The transistor of claim 8, wherein the spacer comprises a material of the group consisting of silicon-germanium, a polymer, silicon, silicon oxide, and silicon nitride.

10. The transistor of claim 8, wherein the source/drain regions in the portion of the substrate below the spacer have a gradually decreasing depth towards the gate.

11. The transistor of claim 8, comprising a further spacer on a lateral wall of the gate, essentially above the spacer, and having a thickness smaller than a thickness of the spacer.

12. The transistor of claim 11, wherein the further spacer is a convex spacer.

13. The method of claim 3, wherein the annealing is hydrogen annealing.
